(19) United States
(12) Patent Application Publication
(10) Pub. No.: US 2021/0057385 A1
(43) Pub. Date: Feb. 25, 2021

(54) LOCKABLE SEMICONDUCTOR DIE, AN ELECTRONIC DEVICE INCLUDING LOCKABLE SEMICONDUCTOR DIES AND METHOD OF PRODUCTION

(71) Applicant: KING ABDULLAH UNIVERSITY OF SCIENCE AND TECHNOLOGY, Thuwal (SA)

(72) Inventors: Mohamed Tarek GHONEIM, Mohandessin (EG); Muhammad Mustafa HUSSAIN, Hercules, CA (US)

(21) Appl. No.: 16/960,349

(22) PCT Filed: Nov. 20, 2018
(86) PCT No.: PCT/IB2018/059129

§ 371 Date: Jul. 7, 2020

Related U.S. Application Data
(60) Provisional application No. 62/618,211, filed on Jan. 17, 2018.

(51) Int. Cl. H01L 25/065; H01L 23/00

(52) U.S. Cl. CPC H01L 25/0657; H01L 24/13; H01L 24/48

(57) ABSTRACT

A lockable semiconductor die includes a first die portion having electrical contacts and a second die portion having electrical contacts electrically coupled to the electrical contacts of the first die portion. The second die portion has a first geometry configured to lock into a corresponding second die portion of another lockable semiconductor die having a second geometry that is inverse to the first geometry. The first and second die portions of the lockable semiconductor die are monolithic.

### CROSS-REFERENCE TO RELATED APPLICATIONS

This application claims priority to U.S. Provisional Patent Application No. 62/618,211, filed on Jan. 17, 2018, entitled “LOCKABLE SEMICONDUCTOR DIE, AN ELECTRONIC DEVICE INCLUDING LOCKABLE SEMICONDUCTOR DIES AND METHOD OF PRODUCTION,” the disclosure of which is incorporated herein by reference in its entirety.

### BACKGROUND

### TECHNICAL FIELD

Embodiments of the disclosed subject matter generally relate to a lockable semiconductor die, an electronic device including lockable semiconductor dies, and method of production.

### DISCUSSION OF THE BACKGROUND

As electronic technology advances, there is an ever-increasing need to reduce the size of electronic devices. Electronic devices comprise dies carrying semiconductor devices, each die typically being separately packaged in a housing. For example, a processor and a memory are separately packaged in separate housings, each having external pins and connections arrays having tiny pads (e.g., ˜ 10's of μm wide) requiring wire bonded using special equipment to the package the external pins. Thus, the lateral surface area covered by an externally connected processor and memory includes the amount of area occupied by the housing of both devices. However, the actual die area typically occupies less than 25% of the overall lateral size of the housing. This wasted space is compounded by the area wasted by the interconnects to connect the processor and memory and to establish proper connection on the circuit board.

Although scaling of the size of electronic devices has steadily followed Moore's law, which predicts a doubling of the number of transistors integrated per unit area every two years, transistor dimensions are approaching physical scaling limits. Accordingly, techniques have been developed to minimize the surface area covered by electronic devices.

One set of techniques is commonly referred to as three-dimensional integration, which generally focus on stacking multiple silicon dies on top of each other so that the number of transistors is doubled without doubling the used surface area. This set of techniques includes: (i) wafer thinning to reduce the thickness per silicon die and the overall stack of multiple dies; (ii) flip chip technology were one die is flipped so that the circuitry on top side can be connected to another circuitry on the top side of a bottom die; (iii) through silicon via (TSV) technology where multiple dies are connected by making an opening in the top die through the whole thickness and filling it with conductive material to establish connections between the top and bottom dies; and (iv) two active surfaces dies where a die has circuitry on both its surfaces and is connected to another die in the bottom and on top.

A common problem of these three-dimensional integration techniques is inefficient heat dissipation. Specifically, the stacked dies typically have the same lateral dimensions and are connected to each other for electrical functionality, and thus the heat dissipation path from the lower dies is restricted to these connections all the way to the top die, which has an effective cooling interface to dissipate heat. Although only a portion of the heat generated by the lower dies reach the top die, the heat at the top die is still significantly higher than the heat generated by the top die itself, and thus these three-dimensional integration techniques require a larger cooling area and more complex cooling structure compared to what would be required if the dies were laterally arranged. This typically results in the cooling structure occupying a larger lateral area than the dies themselves, which can defeat the space-saving goals of three-dimensional integration.

Moreover, stacking dies imposes higher risks and reliability issues, particularly for the lower dies. A common failure in stacked dies is thermal runaway where an increased temperature results in an increased current flow, which generates more heat through joule heating, and this cycle becoming a positive feedback loop that eventually leads to die failure. Furthermore, alignment of three-dimensional stacked dies is extremely challenging.

Thus, it would be desirable to provide for semiconductor dies and electronic devices comprising semiconductor dies that minimize lateral surface area without also resulting in the thermal dissipation issues of known three-dimensional integration techniques.

### SUMMARY

According to an embodiment, a lockable semiconductor die includes a first die portion having electrical contacts and a second die portion having electrical contacts electrically coupled to the electrical contacts of the first die portion. The second die portion has a first geometry configured to lock into a corresponding second die portion of another lockable semiconductor die having a second geometry that is inverse to the first geometry. The first and second die portions of the lockable semiconductor die are monolithic.

According to another embodiment, there is an electronic device, which comprises a first lockable semiconductor die, comprising a first die portion having electrical contacts and a second die portion having electrical contacts electrically coupled to the electrical contacts of the first die portion. The first and second die portions are monolithic. The electronic device also comprises a second lockable semiconductor die, comprising a first die portion having electrical contacts and a second die portion having electrical contacts electrically coupled to the electrical contacts of the first die portion. The first and second die portions are monolithic. The second die portion of the first lockable semiconductor die has a first geometry and the second die portion of the second lockable semiconductor die has a second geometry. The first and second geometries are inverse of each other and configured to lock the second die portions of the first and second lockable semiconductor dies to each other.

According to a further embodiment, there is a method for producing an electronic device. At least a portion of a first semiconductor die is removed to form a first die portion and a second die portion. The first die portion has electrical contacts and the second die portion includes electrical contacts that are electrically coupled to the electrical contacts of the first die portion. At least a portion of a second semiconductor die is removed to form a first die portion and a second die portion. The first die portion has electrical contacts and the second die portion includes electrical contacts that are electrically coupled to the electrical contacts of the first die portion. The first and second semiconductor dies are physically and electrically coupled to each other by locking the second die portions to each other.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1A is a top perspective view schematic diagram of lockable semiconductor die according to an embodiment;

FIG. 1B is a bottom perspective view schematic diagram of lockable semiconductor die according to an embodiment;

FIG. 1C is a top perspective view schematic diagram of lockable semiconductor die according to an embodiment;

FIGS. 2A and 2B are top perspective view schematic diagrams of lockable semiconductor dies according to embodiments;

FIGS. 3A and 3B are top perspective view schematic diagrams of lockable semiconductor dies according to embodiments;

FIGS. 4A and 4B are top perspective view schematic diagrams of lockable semiconductor dies according to an embodiment;

FIG. 4C is a side view schematic diagram of lockable semiconductor dies according to an embodiment;

FIGS. 5A and 5B are top perspective view schematic diagrams of lockable semiconductor dies according to an embodiment;

FIG. 5C is a side view schematic diagram of lockable semiconductor dies according to an embodiment;

FIG. 6 is a side view schematic diagram of lockable semiconductor dies according to an embodiment;

FIGS. 7A and 7B are top perspective view schematic diagrams of lockable semiconductor dies according to an embodiment;

FIG. 7C is a top view schematic diagram of lockable semiconductor dies according to an embodiment;

FIG. 8 is a side view schematic diagram of an electronic device with lockable semiconductor dies according to an embodiment;

FIG. 9 is a flowchart of a method of producing an electronic device with lockable semiconductor dies according to an embodiment;

FIG. 10 is a flowchart of a method of producing a lockable semiconductor die according to an embodiment;

FIGS. 11A-11C are schematic diagrams of a method of producing a lockable semiconductor die according to an embodiment;

FIG. 12 is a flowchart of a method of producing a lockable semiconductor die according to an embodiment; and

FIGS. 13A-13J are schematic diagrams of a method of producing a lockable semiconductor die according to an embodiment.

### DETAILED DESCRIPTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of semiconductor dies and electronic devices including semiconductor dies.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

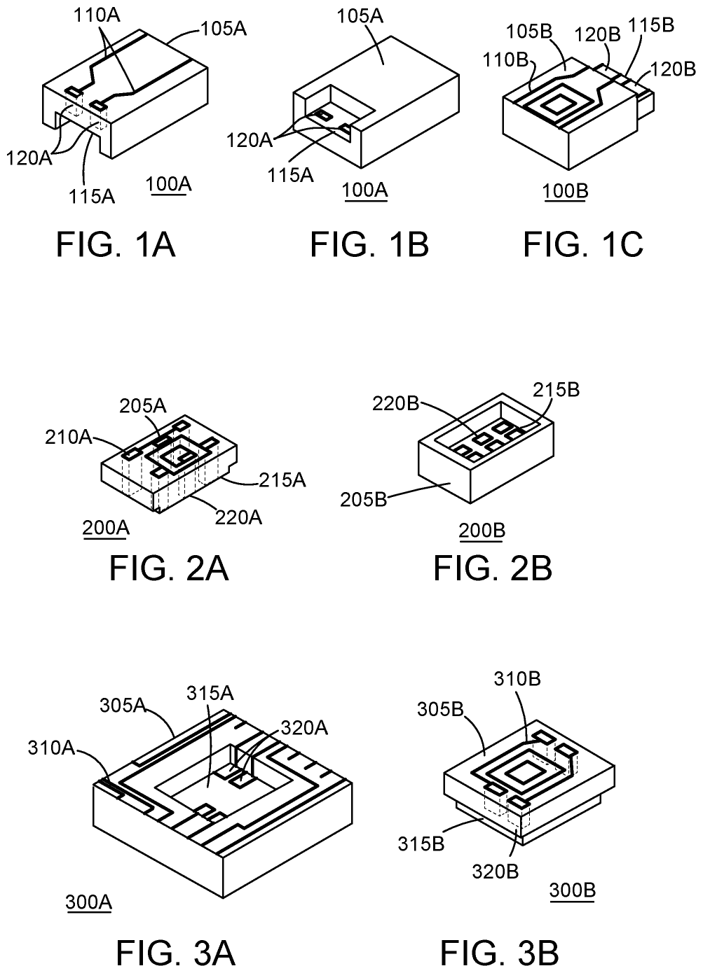

Referring now to FIGS. 1A-1C, a lockable semiconductor die 100A or 100B includes a first die portion 105A or 105B having electrical contacts 110A or 110B. A second die portion 115A or 115B has electrical contacts 120A or 120B electrically coupled to the electrical contacts 110A or 110B of the first die portion 105A or 105B. The second die portion 115A or 115B has a first geometry configured to lock into a corresponding second die portion 105B or 105A of another lockable semiconductor die 100B or 100A having a second geometry that is inverse to the first geometry. The first 105A or 105B and second 115A or 115B die portions of the lockable semiconductor die 100A or 100B are monolithic.

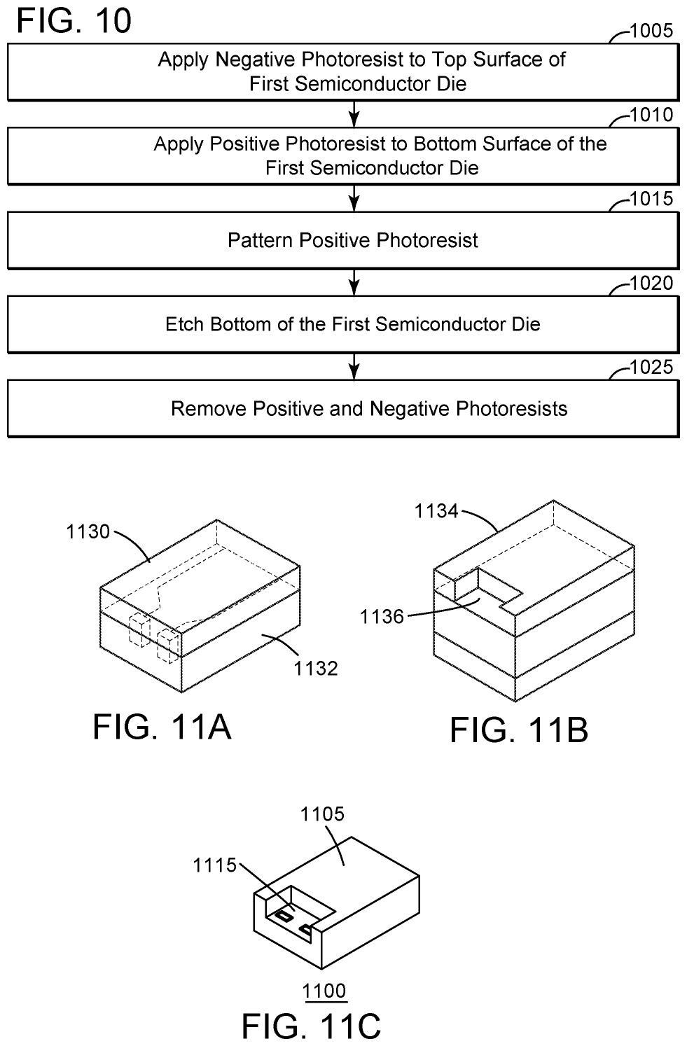

In this embodiment, the lockable semiconductor dies 100A and 100B include the second portion 115A and 115B on a lateral side of the semiconductor die. The second die portion 115A in FIGS. 1A and 1B includes a top portion that laterally extends beyond a bottom portion of the second die portion 115A, and the second die portion 115B in FIG. 10 has a second die portion 115B with a bottom portion that laterally extends beyond a top portion of the second die portion 115B.

As will be appreciated from FIGS. 1A-1C, the inverse geometry of the second die portion 115B or 115A of the another lockable semiconductor die 100B or 100A is such that it mates and locks with the second die portion 115A or 115B of the lockable semiconductor die 100A or 100B. By including electrical contacts 115A and 115B on the second die portions 115A and 115B, locking of the two dies not only structurally connects the two dies but also electrically couples the two dies without requiring additional materials to join the two dies.

As will be discussed in more detail below, the first 105A and 105B and second 115A and 115B die portions of the lockable semiconductor die 100A and 100B are monolithic because they are formed from a common substrate. The disclosed monolithic structure is structurally different from a structure formed of two separate pieces, particularly providing much better structural integrity.

FIGS. 2A-3B illustrate semiconductor dies with other geometries. The reference numbers in these figures correspond to those in FIGS. 1A-1C. Specifically, assuming X corresponds to the figure number, X00A designates the first lockable semiconductor die, X05A designates the first die portion of the first lockable semiconductor die, X10A designates the electrical contacts of the first die portion of the first lockable semiconductor die, X15A designates the second die portion of the first lockable semiconductor die, X20A designates the electrical contacts of the second die portion of the first lockable semiconductor die, X00B designates the second lockable semiconductor die, X05B designates the first die portion of the second lockable semiconductor die, X10B designates the electrical contacts of the first die portion of the second lockable semiconductor die, X15B designates the second die portion of the second lockable semiconductor die, X20B designates the electrical contacts of the second die portion of the second lockable semiconductor die.

As illustrated in FIG. 2A, the second die portion 215A is arranged on the bottom side of the semiconductor die and in FIG. 2B the second portion 215B is arranged in a top side of the semiconductor die. Similarly, as illustrated in FIG. 3A, the second portion 315A is arranged in a top side of the semiconductor die and in FIG. 3B the second portion 315B is arranged on a bottom side of the semiconductor die.

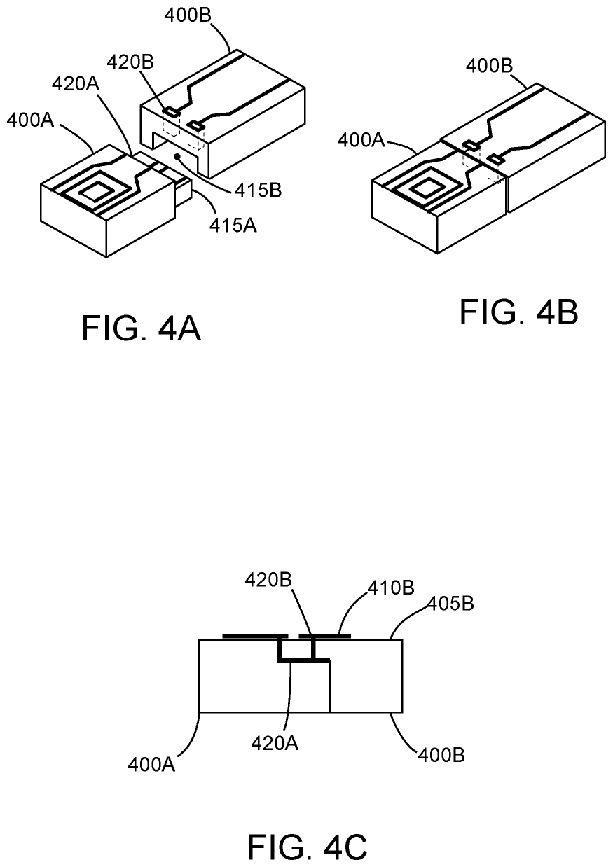

Examples of electronic devices comprising two locked dies will now be described in connection with FIGS. 4A-7C. Referring now to FIGS. 4A-4C, a first lockable semiconductor die 400A has a second die portion 415A with electrical contacts 420A and a second lockable semiconductor die 400B includes a second die portion 415B with electrical contacts 420B. The geometries of the second die portions 415A and 415B are inverse of each other and configured to lock the first 400A and second 400B lockable semiconductor dies to each other (see FIG. 4B). As illustrated in the side view of FIG. 4C, the electrical contacts 420B of the second lockable semiconductor die 400B are in the form of through-silicon-vias (TSVs) so that the electrical contacts 420A of the first semiconductor die 400A are electrically coupled to the electrical contacts 410B of the first die portion 405B of the second semiconductor die 400B.

The use of second die portions 415A and 415B having geometries that are inverse to each other provides for the locking of the first 400A and second 400B semiconductor dies, which establishes a physical and electrical coupling of the dies. In some embodiments, the physical and electrical coupling can be enhanced by providing a physical and/or electrical bonding agent between the two locking second die portions 415A and 415B. For example, a metallic, alloyed, and/or fusible alloy material can be arranged on one or both of the second die portions 415A and 415B prior to locking, and heat can be applied to the second die portions 415A and 415B once the two portions are locked to each other to melt the material and form an enhanced physical and electrical coupling.

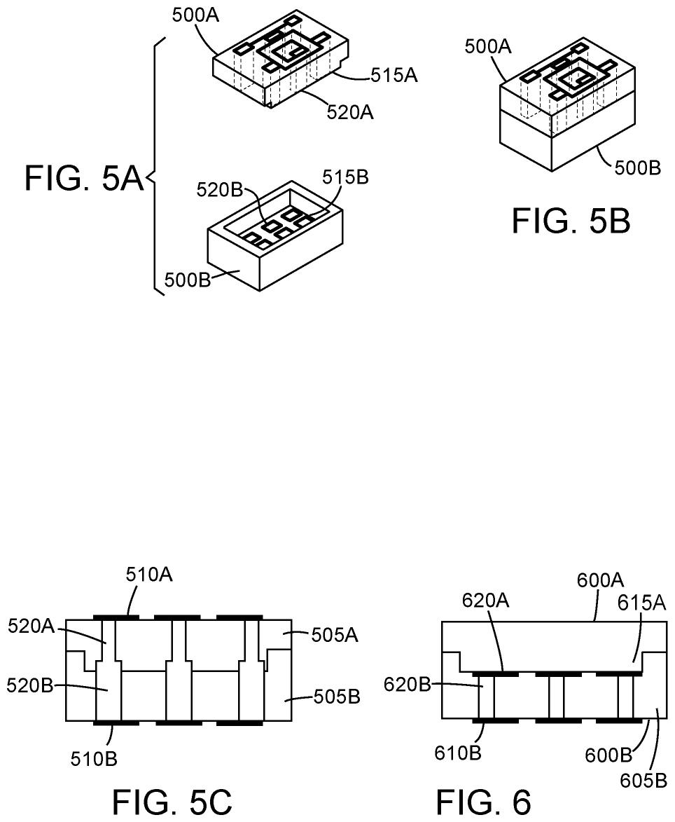

Referring now to FIGS. 5A-5C, a first lockable semiconductor die 500A has a second die portion 515A with electrical contacts 520A and a second lockable semiconductor die 500B includes a second die portion 515B with electrical contacts 520B. The geometries of the second die portions 515A and 515B are inverse of each other and configured to lock the first 500A and second 500B lockable semiconductor dies to each other (see FIG. 5B). As illustrated in the side view of FIG. 5C, the electrical contacts 520A and 520B of the second lockable semiconductor dies 500A and 500B are in the form of through-silicon-vias so that the electrical contacts 520A and 520B are respectively electrically coupled to the electrical contacts 510B and 510A of the first die portions 505B and 505A. Similar to the discussion above in connection with FIGS. 4A-4C, the physical and electrical coupling of the first 500A and second 500B semiconductor dies can be enhanced using a physical and/or electrical bonding agent.

FIG. 6 is a side view of a variant of the electronic device in FIGS. 5A-5C. In this variant, only the second lockable semiconductor die 600B includes through-silicon-vias 620B. Specifically, through-silicon-vias 620B electrically connect the electrical contacts 620A of the second die portion 615A of the first lockable semiconductor die 600A to the electrical contacts 610B of the first die portion 605B of the second lockable semiconductor die 600B. Thus, in this variant, the electrical contacts that are illustrated on the top side of the first lockable semiconductor die 500A (i.e., in the first die portion) in FIGS. 5A-5C are instead located in the second die portion in FIG. 6.

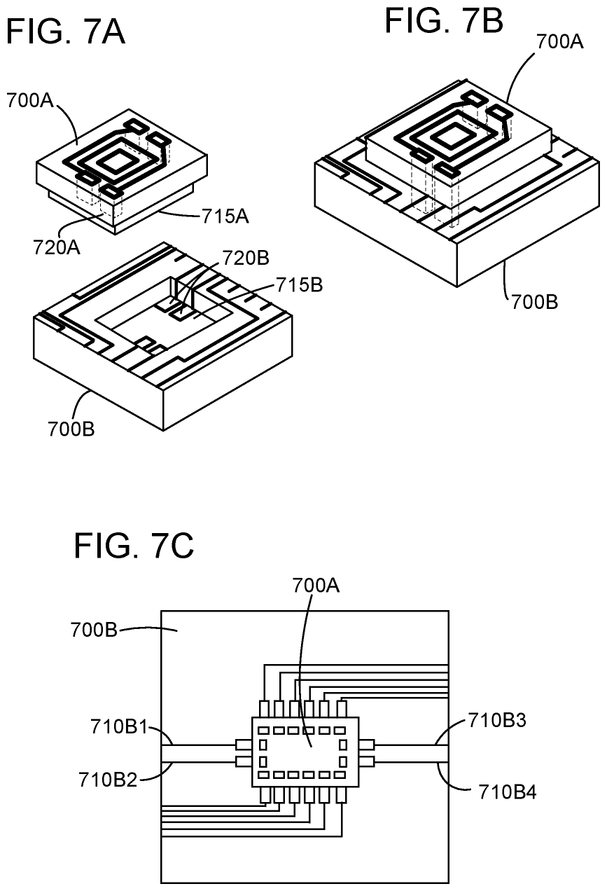

Referring now to FIGS. 7A-7C, a first lockable semiconductor die 700A has a second die portion 715A with electrical contacts 720A and a second lockable semiconductor die 700B includes a second die portion 715B with electrical contacts 720B. The geometries of the second die portions 715A and 715B are inverse of each other and configured to lock the first 700A and second 700B lockable semiconductor dies to each other (see FIG. 7B). As illustrated in the top view of FIG. 7C, the first die portion 705B of the second lockable semiconductor die 700B includes electrical contacts 710B1-710B4 that allow external electrical coupling to the first lockable semiconductor die 700A. Similar to the discussion above in connection with FIGS. 4A-4C and 5A-5C, the physical and electrical coupling of the first 700A and second 700B semiconductor dies can be enhanced using a physical and/or electrical bonding agent.

As will be appreciated from FIGS. 7A-7C, the first lockable semiconductor die 700A is smaller than the second lockable semiconductor die 700B. Thus, even though this arrangement involves a vertical stacking, the second lockable semiconductor die 700B is able to better dissipate heat in areas that are not occupied by the first lockable semiconductor die 700A, which results in less heat being radiate onto the first lockable semiconductor die 700A. Accordingly, unlike conventional stacking techniques in which all of the dies have the same general lateral dimensions, the stacked arrangement in FIGS. 7A-7C does not require the same extensive cooling arrangements as the conventional techniques and also result in lesser degradation of the first semiconductor 700A die compared the conventional stacking arrangement, which is due less heat being radiated into it from the second lockable semiconductor die 700B.

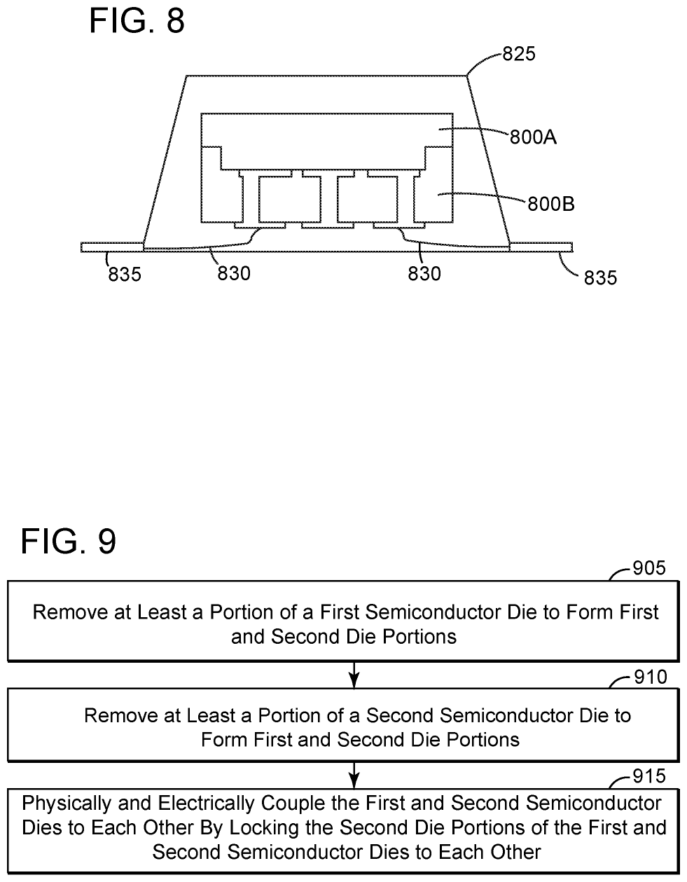

The electronic devices having two lockable semiconductor dies described above can be advantageously contained in a common housing, an example of which is illustrated in FIG. 8. Specifically, the first 800A and second 800B lockable semiconductor dies can be contained in common housing 825. Thus, only a single set of electrical couplings 830 are required to electrically couple the first 800A and second 800B lockable semiconductor dies to external leads 835. In contrast, conventional electronic devices typically included a single die per housing, which doubles the wasted space occupied by the housing compared to the disclosed embodiments. Further, the amount of time to produce the electronic devices can be reduced because only a single set of electrical couplings 830 are required to electrically couple the first 800A and second 800B lockable semiconductor dies to external leads 835.

A method for producing an electronic device having lockable semiconductor dies will now be described in connection with FIGS. 1A-1C and 9. However, this method is equally applicable to producing the other disclosed lockable semiconductor dies. Initially, at least a portion of a first semiconductor die is removed to form first 105A and second 115A die portions (step 905). Next, at least a portion of a second semiconductor die is removed to form first 105B and second 115B die portions (step 910). The first 100A and second 100B semiconductor dies are then physically and electrically coupled to each other by locking the second die portions 115A and 115B of the first 100A and second 100B semiconductor dies to each other (step 915). Additional steps can be performed, including arranging the locked dies in a housing and coupling the locked dies to electrical leads that are external to the housing.

A method for forming one of the lockable semiconductor dies will now be described in connection with FIGS. 10 and 11A-11C. Initially, a negative photoresist 1130 is applied to a top surface of the first semiconductor die 1132 (step 1005 and FIG. 11A). The first semiconductor die 1132 is then flipped and a positive photoresist 1134 is applied to a bottom surface of the first semiconductor die 1132 (step 1010 and FIG. 11B). The positive photoresist 1134 is patterned to form an opening 1136 for the area where the second die portion will be formed (step 1015 and FIG. 11B). The bottom of the first semiconductor die 1132 is then etched to form the first 1105 and second 1115 die portions and then the positive 1134 and negative 1130 photoresists are removed to result in a lockable semiconductor die 1100 (steps 1020 and 1025 and FIG. 11C). The etching can be performed using deep reactive ion etching (DRIE) techniques.

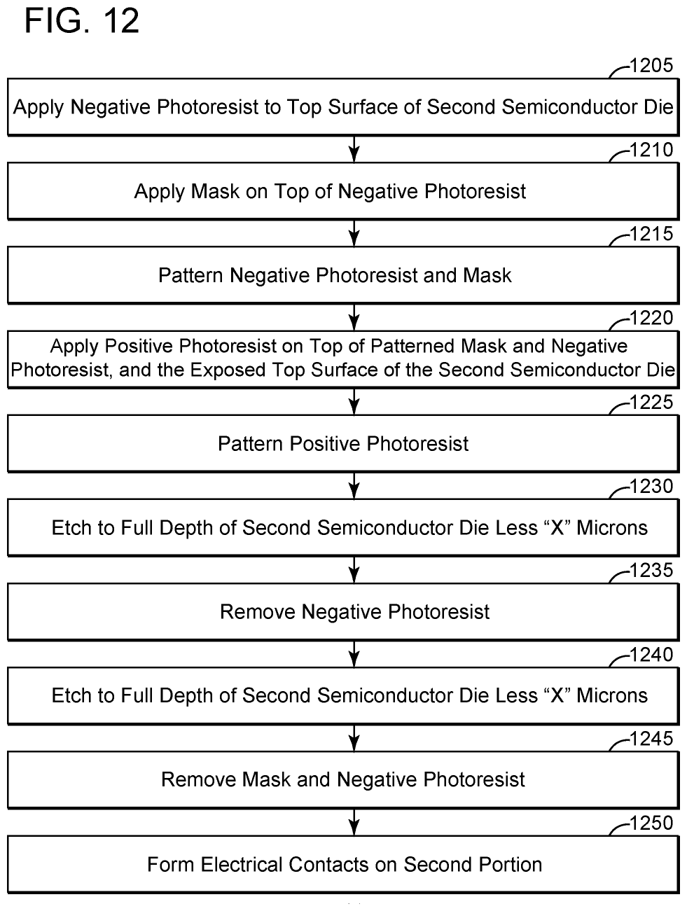

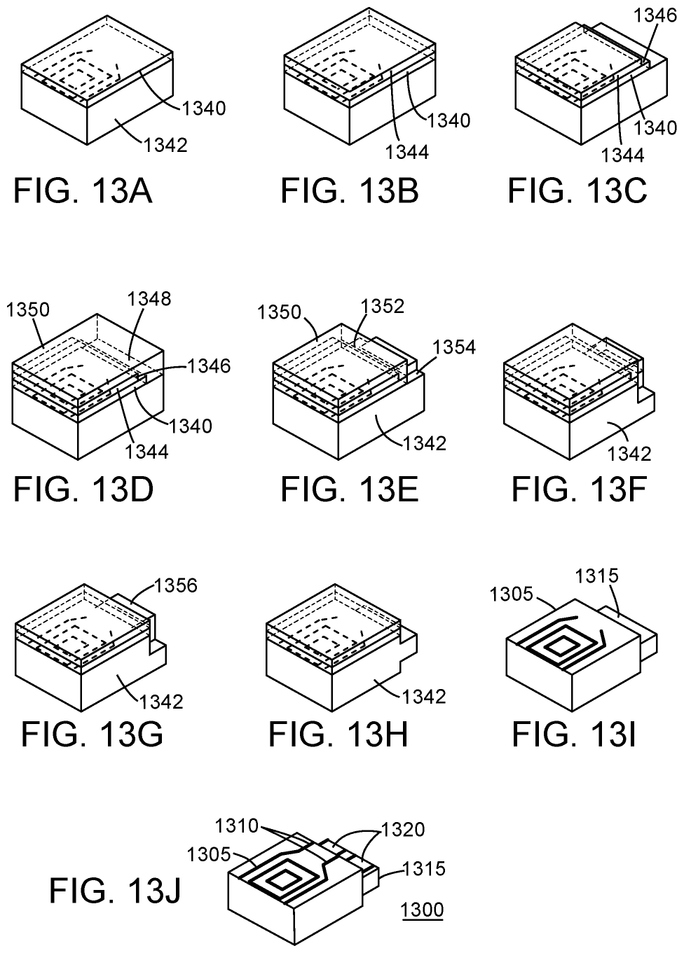

A method for forming another one of the lockable semiconductor dies will now be described in connection with FIGS. 12 and 13A-13F. Initially, a negative photoresist 1340 is applied to a top surface of the second semiconductor die 1342 (step 1205 and FIG. 13A). A mask 1344 is then formed on top of the negative photoresist 1340 (step 1210 and FIG. 13B). The negative photoresist 1340 and mask 1344 are then patterned (step 1215 and FIG. 13C). Specifically, the patterning of the mask 1344 exposes a portion 1346 of the negative photoresist and the negative photoresist 1340 is patterned a to expose portion 1348 of the second semiconductor die 1342.

A positive photoresist 1350 is applied on top of the patterned mask 1340, the exposed portion 1346 of the negative photoresist 1340, and the exposed portion 1348 of the second semiconductor die 1342 (step 1220 and FIG. 13D). The positive photoresist 1350 is then patterned to expose portions 1352 and 1354 of the second semiconductor die 1342 (step 1225 and FIG. 13E). The exposed portions 1352 and 1354 of the second semiconductor substrate 1342 are etched to the full depth of the second semiconductor substrate 1342 less a predetermined number of microns X(step 1230 and FIG. 13F). The etching can be performed using DRIE techniques. The predetermined number of microns X corresponds to the desired height of the second die portion 1315, which in turn corresponds to the height of the inverse geometry of the second die portion of the corresponding locking semiconductor die (see, for example the second die portion 1115 in FIG. 11C).

The positive photoresist 1350 is then removed (step 1235 and FIG. 13G). The positive photoresist can be removed using, for example, a metal ion free (MIF) developer for which the negative photoresist and the mask is insoluble, such as 726 MIF from MicroChemicals. The remaining portion 1356 of the exposed portion 1348 of the second semiconductor die 1342 is etched to the full depth of the second semiconductor substrate 1342 less a predetermined number of microns X (step 1240 and FIGS. 13G and 13H). The etching can be performed using DRIE techniques. The mask 1344 and negative photoresist 1350 are then removed to expose the remaining portions of the semiconductor die 1342 (step 1245 and FIG. 13I). As illustrated in FIG. 13I, the second semiconductor die 1342 now has a first die portion 1305 and a second die portion 1315. Electrical contacts 1320 are formed on the second die portion 1315 and are electrically coupled to the and electrical contacts 1310 of the first die portion 1305 to form a second lockable semiconductor die 1300 (step 1250 and FIG. 13J). The electrical contacts 1310 can be formed, for example using atomic layer deposition (ALD), which can involve patterning using a photoresist, laser, or any other technique to separate the electrical contacts 1310 from each other.

The discussion above uses the terms first and second to distinguish between different semiconductor dies and portions of the semiconductor dies. Thus, whether something is referred to as first or second should not be considered limiting and the die or portion being referred to could also be referred to as a second or first die or portion.

Although the lockable dies have been disclosed having particular geometries in the second die portion, these are merely non-limiting examples and other geometries can be employed so long as two dies to be locked together have second die portions with inverse geometries.

The disclosed embodiments provide a lockable semiconductor die, electronic device including lockable semiconductor ides, and methods of production. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. A lockable semiconductor die, comprising:
a first die portion having electrical contacts;
a second die portion having electrical contacts electrically coupled to the electrical contacts of the first die portion,
wherein the second die portion has a first geometry configured to lock into a corresponding second die portion of another lockable semiconductor die having a second geometry that is inverse to the first geometry, and
wherein the first and second die portions of the lockable semiconductor die are monolithic.

2. The lockable semiconductor die of claim 1, wherein the second die portion of the lockable semiconductor die is arranged on a lateral side of the semiconductor die.

3. The lockable semiconductor die of claim 2, wherein the second die portion of the lockable semiconductor die has a top portion that laterally extends beyond a bottom portion of the second die portion.

4. The lockable semiconductor die of claim 2, wherein the second die portion of the semiconductor die has a bottom portion that laterally extends beyond a top portion of the second die portion.

5. The lockable semiconductor die of claim 1, wherein the second die portion of the semiconductor die is arranged on a bottom side of the semiconductor die.

6. The lockable semiconductor die of claim 5, wherein the semiconductor die is smaller than the another semiconductor die.

7. The lockable semiconductor die of claim 1, wherein the second die portion of the semiconductor die is arranged in a top portion of the semiconductor die.

8. The lockable semiconductor die of claim 1, wherein the electrical contacts of the second die portion of the semiconductor die are configured to be electrically coupled to electrical contacts on the second die portion of the other semiconductor die when the second portions of the semiconductor die and the another semiconductor die are locked into each other.

9. An electronic device, comprising:
a first lockable semiconductor die, comprising
a first die portion having electrical contacts;
a second die portion having electrical contacts electrically coupled to the electrical contacts of the first die portion, wherein the first and second die portions are monolithic;
a second lockable semiconductor die, comprising
a first die portion having electrical contacts;
a second die portion having electrical contacts electrically coupled to the electrical contacts of the first die portion, wherein the first and second die portions are monolithic,
wherein the second die portion of the first lockable semiconductor die has a first geometry and the second die portion of the second lockable semiconductor die has a second geometry, wherein the first and second geometries are inverse of each other and configured to lock the second die portions of the first and second lockable semiconductor dies to each other.

10. The electronic device of claim 9, further comprising:
a common housing containing the first and second lockable semiconductor dies.

11. The electronic device of claim 10, wherein the common housing includes external electrical contacts that are electrically coupled to the electrical contacts of the second semiconductor portion of at least one of the first and second lockable semiconductor dies.

12. The electronic device of claim 9, wherein the second die portion of the first and second lockable semiconductor dies is arranged on a lateral side of the first and second lockable semiconductor dies, the second die portion of the first lockable semiconductor die has a top portion that laterally extends beyond a bottom portion of the second die portion of the first lockable semiconductor die, and the second die portion of the second lockable semiconductor die has a bottom portion that laterally extends beyond a top portion of the second die portion of the second lockable semiconductor die.

13. The electronic device of claim 9, wherein the second die portion of the first lockable semiconductor die is arranged on a bottom side of the first semiconductor lockable die and the second die portion of the second lockable semiconductor die is arranged in a top side of the second lockable semiconductor die.

14. The electronic device of claim 13, wherein the first lockable semiconductor die is smaller than the second lockable semiconductor die.

15. The electronic device of claim 9, wherein the electrical contacts of the second die portion of the first lockable semiconductor die are configured to be electrically coupled to electrical contacts on the second die portion of the second lockable semiconductor die when the second portions of the first and second lockable semiconductor dies are locked into each other.

16. A method for producing an electronic device, the method comprising:
removing at least a portion of a first semiconductor die to form a first die portion and a second die portion, wherein the first die portion has electrical contacts, and the second die portion includes electrical contacts that are electrically coupled to the electrical contacts of the first die portion;
removing at least a portion of a second semiconductor die to form a first die portion and a second die portion, wherein the first die portion has electrical contacts, and the second die portion includes electrical contacts that are electrically coupled to the electrical contacts of the first die portion; and
physically and electrically coupling the first and second semiconductor dies to each other by locking the second die portions to each other.

17. The method of claim 16, further comprising:
heating the second die portions of the first and second semiconductor dies to melt corresponding electrical contacts of the second die portion of the first and second semiconductor dies.

18. The method of claim 16, wherein the removal of at least a portion of the first and second semiconductor dies is performed using deep reactive ion etching, DRIE.

19. The method of claim 18, wherein removal of the at least a portion of the first semiconductor die comprises:
forming a negative photoresist on top of first semiconductor die;
patterning the negative photoresist;
forming a positive photoresist on top of the patterned negative photoresist;
patterning the positive photoresist; and
performing deep reactive ion etching, DRIE, from the top of the first semiconductor die to form the second die portion in a predetermined geometry.

20. The method of claim 19, wherein removal of the at least a portion of the second semiconductor die comprises:
forming a negative photoresist on top of the second semiconductor die;
forming a positive photoresist on a bottom of the second semiconductor die;
patterning the positive photoresist; and
performing deep reactive ion etching from the bottom of the second semiconductor die to form the second die portion in a predetermined geometry.
